(19) United States
(12) Patent Application Publication
(10) Pub. No.: US 2024/0395764 A1
(43) Pub. Date: Nov. 28, 2024

(54) BONDING APPARATUS FOR SEMICONDUCTOR DEVICE AND METHOD OF BONDING SEMICONDUCTOR DEVICES USING THE SAME

(71) Applicant: SAMSUNG ELECTRONICS CO., LTD., SUWON-SI (KR)

(72) Inventors: Gyeongjae JO, Suwon-si (KR); Sangcheon PARK, Suwon-si (KR); Youngkun JEE, Suwon-si (KR)

(21) Appl. No.: 18/624,233

(22) Filed: Apr. 2, 2024

(30) Foreign Application Priority Data
May 24, 2023 (KR) 10-2023-0066694

(51) Int. Cl. H01L 23/00

(52) U.S. Cl. CPC H01L 24/74; H01L 24/80; H01L 2224/74; H01L 2224/80895; H01L 2224/80896; H01L 2924/40

(57) ABSTRACT

A bonding apparatus for a semiconductor device including: a substrate state having a seating surface on which a first semiconductor device is placed; a head portion having a lower surface, the head portion configured to hold a second semiconductor device on the lower surface to face the first semiconductor device, the lower surface including a first portion having a first height from the seating surface and a second portion having a second height from the seating surface, the second height being greater than the first height, the lower surface being inclined at an angle with respect to the seating surface; and a transfer portion provided on the head portion to move the head portion, the transfer portion configured to press the head portion from the first portion to the second portion such that the first and second semiconductor devices are bonded to each other.

### PRIORITY STATEMENT

This application claims priority under 35 U.S.C. § 119 to Korean Patent Application No. 10-2023-0066694, filed on May 24, 2023 in the Korean Intellectual Property Office (KIPO), the contents of which are incorporated by reference herein in its entirety.

### 1. TECHNICAL FIELD

Example embodiments relate to a bonding apparatus for a semiconductor device and a method of bonding semiconductor devices using the same. More particularly, example embodiments relate to a semiconductor device bonding apparatus for stacking a plurality of semiconductor devices on one another and a method of bonding semiconductor devices using the same.

### 2. DISCUSSION OF THE RELATED ART

When bonding multiple semiconductor devices together, a Chip Interface Gap-less structure that minimizes a space between the semiconductor devices may be used to maximize a performance of a semiconductor package. A hybrid copper bonding process may be used to directly bond the semiconductor devices together. When the semiconductor device is thick in the hybrid copper bonding process, deformation of the semiconductor device may be minimal and it may be difficult to remove voids between the semiconductor devices. When the semiconductor device is thin, excessive deformation of the semiconductor device may occur due to bending stress, and the semiconductor device may be damaged by internal peeling or the like.

### SUMMARY

Example embodiments provide a bonding apparatus for semiconductor device having a structure capable of removing voids between semiconductor devices without causing damage to the semiconductor device during a process of bonding the semiconductor devices.

Example embodiments provide a method of bonding using the bonding apparatus.

According to example embodiments, a bonding apparatus for a semiconductor device comprising: a substrate state having a seating surface on which a first semiconductor device is placed; a head portion having a lower surface, the head portion configured to hold a second semiconductor device on the lower surface to face the first semiconductor device, the lower surface including a first portion having a first height from the seating surface and a second portion having a second height from the seating surface, the second height being greater than the first height, the lower surface being inclined at an angle with respect to the seating surface; and a transfer portion provided on the head portion to move the head portion, the transfer portion configured to press the head portion from the first portion to the second portion such that the first and second semiconductor devices are bonded to each other.

According to example embodiments, a bonding apparatus for a semiconductor device for a semiconductor device comprising: a substrate stage having a seating surface on which a first semiconductor device is supported; a head portion having a lower surface inclined at an angle with respect to the seating surface of the substrate stage, the head portion configured to hold a second semiconductor device on the lower surface of the head portion to face the first semiconductor device; and a transfer portion provided on the head portion to move the head portion, the transfer portion configured to press the second semiconductor device onto the first semiconductor device from a first portion of the lower surface to a second portion of the lower surface, the first portion of the lower surface having a first height from the seating surface, the second portion of the lower surface having a second height from the seating surface, the second height being greater than the first height.

According to example embodiments, a bonding apparatus for a semiconductor device comprising: a substrate stage having a seating surface that is configured to support a first semiconductor device during a process of bonding a second semiconductor device on the first semiconductor device; a head portion having a lower surface that is inclined at a predetermined angle with respect to the seating surface of the substrate stage, the head portion configured to temporarily hold the second semiconductor device on the lower surface using vacuum pressure such that the second semiconductor device faces the first semiconductor device; and a transfer portion provided on the head portion, the transfer portion configured to press the second semiconductor device onto the first semiconductor device from a first portion of the lower surface toward a second portion of the lower surface, the first portion of the lower surface having a first height from the seating surface, the second portion of the lower surface having a second height from the seating surface, the second height being greater than the first height.

According to example embodiments, a bonding apparatus for a semiconductor device may include a substrate stage having a seating surface for supporting a first semiconductor device, a head portion having a lower surface and configured to temporarily hold a second semiconductor device on the lower surface so as to face the first semiconductor device, the lower surface including a first portion having a first height from the seating surface and a second portion having a second height greater than the first height, the lower surface inclined at a predetermined angle from the seating surface, and a transfer portion provided on the head portion to move the head portion, the transfer portion configured to press the head portion from the first portion to the second portion such that the first and second semiconductor devices are bonded to each other.

Accordingly, the bonding apparatus may bond the second semiconductor device to the first semiconductor device supported on the substrate stage using the head portion. The head portion on which the second semiconductor device is secured may have the first and second portions having the different first and second heights from the seating surface. Since the second height of the second portion is greater than the first height of the first portion, the second semiconductor device secured on the lower surface of the head portion may be inclined at the predetermined angle.

When the transfer portion provided on the head portion descends in a vertical direction, the second semiconductor device may be brought into contact with the first semiconductor device on the first portion. When the transfer portion presses the head portion in the vertical direction, the second semiconductor device may be bonded to the first semiconductor device from the first portion to the second portion. Since the first and second semiconductor devices are bonded to each other from the first portion toward the second portion, voids between the first and second semiconductor devices may be moved from the first portion toward the second portion to be discharged to the outside.

Further, since the transfer portion gradually presses the head portion from the first portion toward the second portion, the bonding apparatus may prevent excessive deformation and internal peeling of the second semiconductor device.

### BRIEF DESCRIPTION OF THE DRAWINGS

Example embodiments will be more clearly understood from the following detailed description taken in conjunction with the accompanying drawings. FIGS. 1 to 10 represent non-limiting, example embodiments as described herein.

FIG. 1 is a view illustrating a bonding apparatus for a semiconductor device in accordance with example embodiments.

FIG. 2 is a perspective view illustrating a head portion of the bonding apparatus in FIG. 1.

FIGS. 3,4,5,6,7,8 and 9 are views illustrating processes of bonding a plurality of semiconductor devices using the bonding apparatus in FIG. 1.

FIG. 10 is a view illustrating a bonding apparatus having a rotating portion in accordance with example embodiments.

### DETAILED DESCRIPTION OF EXAMPLE EMBODIMENTS

Example embodiments will now be described more fully hereinafter with reference to the accompanying drawings.

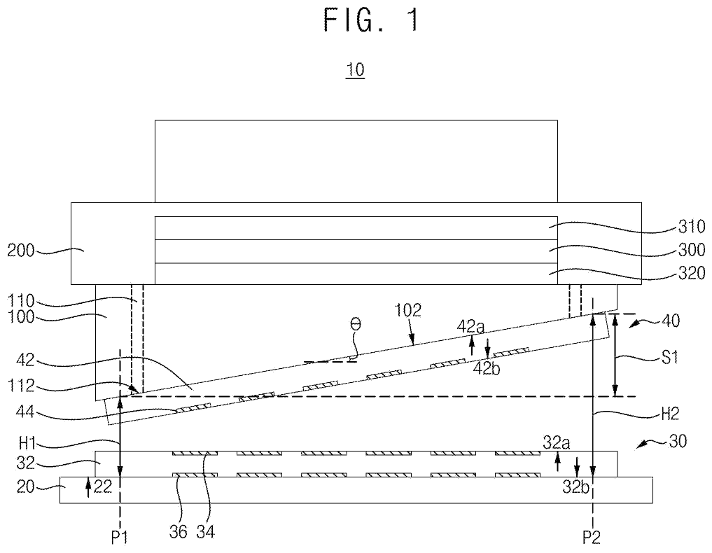

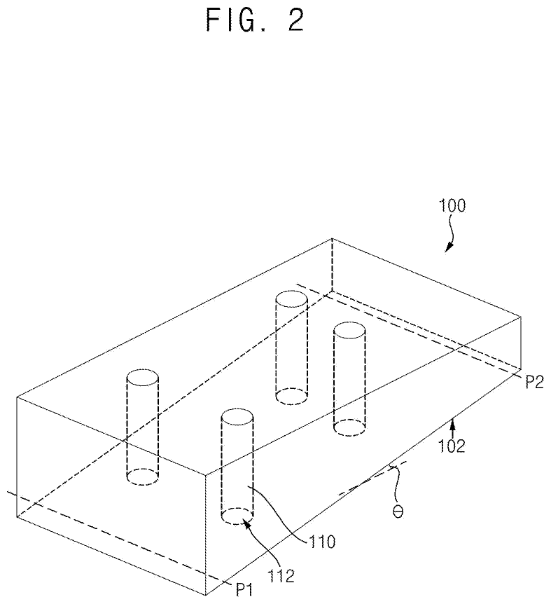

FIG. 1 is a view illustrating a bonding apparatus for a semiconductor device in accordance with example embodiments. FIG. 2 is a perspective view illustrating a head portion of the bonding apparatus in FIG. 1.

Referring to FIGS. 1 and 2, a bonding apparatus 10 for a semiconductor device may include a substrate stage 20 on which a first semiconductor device 30 is placed, a head portion 100 configured to temporarily hold a second semiconductor device 40 on the substrate stage 20, and a transfer portion 200 configured to move the head portion 100. The bonding apparatus 10 may be used to perform a bonding process for bonding a plurality of semiconductor devices. The bonding apparatus 10 may bond the second semiconductor device 40 onto the first semiconductor device 30 to form a semiconductor package.

In example embodiments, the substrate stage 20 may have a seating surface 22 for supporting at least one of the semiconductor devices. For example, the substrate stage 20 may place the first semiconductor device 30 on the seating surface 22. The first semiconductor device 30 is disposed directly on the seating surface 22 of the substrate stage 20. The substrate stage 20 may be provided below the head portion 100.

The semiconductor package including the first and second semiconductor devices 30 and 40 may include a memory device having a stacked chip structure in which a plurality of dies (chips) are stacked. The memory device may include a high bandwidth memory (HBM) device. Alternatively, the semiconductor package may include a semiconductor memory device and a logic semiconductor device having a 3D chip structure.

For example, the first semiconductor device 30 may include a semiconductor wafer, a carrier substrate, a printed circuit board (PCB), a lead frame, and so forth. Each of the first and second semiconductor devices 30 and 40 may include an integrated circuit chip that is formed by performing semiconductor manufacturing processes. For example, each of the first and second semiconductor devices 30 and 40 may include a memory chip or a logic chip.

Hereinafter, the first semiconductor device 30 will be described.

The first semiconductor device 30 may include a first substrate 32 having a first upper surface 32a and a first lower surface 32b opposite to the first upper surface 32a, a first connecting pad 34 provided on the first upper surface 32a, and a first bonding pad 36 provided on the first lower surface 32b. For example, the first connecting pad 34 and the first bonding pad 36 face each other. In addition, the first semiconductor device 30 may further include a first through electrode that penetrates the first substrate 32.

The first upper surface 32a of the first substrate 32 may be referred to as an inactive surface, and the first lower surface 32b of the first substrate 32 may be referred to as an active surface. Circuit patterns may be provided on the first lower surface 32b of the first substrate 32. The first lower surface 32b of the first substrate 32 may be referred to as a front surface on which the circuit patterns are formed, and the first upper surface 32a of the first substrate 32 may be referred to as a backside surface. The circuit patterns may include transistors, diodes, and so forth. The circuit patterns may constitute a plurality of circuit elements. Thus, the first semiconductor device 30 may be referred to as a semiconductor device having a plurality of circuit elements formed therein.

In example embodiments, a first activation layer may be provided on the first lower surface 32b of the first substrate 32. The first activation layer may include an insulating layer, and a plurality of redistribution wirings provided in the insulating layer. The redistribution wiring may be connected to a first end portion of the first through electrode. In addition, the first bonding pad 36 may be connected to the redistribution wiring that is electrically connected to the first through electrode. The insulating layer may include silicon oxide, carbon-doped silicon oxide, silicon carbonitride (SiCN), and so forth.

A conductive bump may be provided on the first bonding pad 36. The conductive bump may facilitate an electrical pathway for connecting the first semiconductor device 30 to another semiconductor device. For example, the first semiconductor device 30 may be mounted on the other semiconductor device via the conductive bump. The conductive bumps may include micro bumps (uBumps).

The first connecting pad 34 may be provided on the first upper surface 32a of the first substrate 32 and may be electrically connected to the first through electrode. The first connecting pad 34 may be electrically connected to a second end portion of the first through electrode opposite to the first end portion of the first through electrode.

The first through electrode may penetrate the first substrate 32 in a thickness direction. For example, the first through electrode may penetrate the first substrate 32 in a vertical direction. The first end portion of the first through electrode may be electrically connected to the redistribution wirings. The second end portion of the first through electrode may be exposed to the first upper surface 32a of the first substrate 32. The first connecting pad 34 may be electrically connected to the exposed second end portion of the first through electrode.

In example embodiments, the second semiconductor device 40 may include a second substrate 42, and a second bonding pad 44 provided on a second lower surface 42b of the second substrate 42. The second semiconductor device 40 may further include a second connecting pad provided on a second upper surface 42a of the second substrate 42, and a second through electrode that penetrates the second substrate 42 in a thickness direction.

The first connecting pad 34, the first bonding pad 36, and the second bonding pad 44 may include aluminum (Al), copper (Cu), tin (Sn), nickel (Ni), gold (Au), platinum (Pt), or an alloy thereof.

The bonding apparatus 10 may mount the second semiconductor device 40 onto the first semiconductor device 30 such that the second lower surface 42b of the second substrate 42 faces the first upper surface 32a of the first substrate 32. The second bonding pads 44 of the second semiconductor device 40 may be directly bonded to the first connecting pads 34 of the first semiconductor device 30. The second bonding pad 44 of the second semiconductor device 40 may be electrically connected to the first connecting pad 34 of the first semiconductor device 30. A lower insulating layer of the second semiconductor device 40 and an upper insulation layer of the first semiconductor device 30 may be directly bonded to each other. A surface area of the second semiconductor device 40 and that of the first semiconductor device 30 may be the same and the two may overlap entirely.

The second semiconductor device 40 may be bonded to the first semiconductor device 30 by a hybrid copper bonding method. Thus, the first connecting pad 34 of the first semiconductor device 30 and the second bonding pad 44 of the second semiconductor device 40 may be bonded to each other by Cu—Cu Hybrid Bonding. For example, pad to pad direct bonding may be formed.

In this embodiment, the semiconductor devices as a multi-chip package are illustrated as including the first and second semiconductor devices 30 and 40. However, it is not limited thereto, and the semiconductor device may include more stacked semiconductor chips. For example, the semiconductor device may include 4, 8, 12, or 16 stacked semiconductor chips.

In example embodiments, the head portion 100 may be configured to temporarily hold the second semiconductor device 40, facilitating the bonding of the second semiconductor device 40 onto the first semiconductor device 30. The head portion 100 may temporarily hold the second semiconductor device 40 such that the second lower surface 42b of the second semiconductor device 40 faces the first upper surface 32a of the first semiconductor device 30.

The head portion 100 may have a lower surface 102 that has a predetermined angle θ with respect to the seating surface 22 of the substrate stage 20. The second semiconductor device 40 temporarily held on the lower surface 102 of the head portion 100 may have the predetermined angle θ with respect to the seating surface 22 of the substrate stage 20. For example, the predetermined angle θ may be within a range of 1 degree to 45 degrees.

The lower surface 102 of the head portion 100 may have a first portion P1 and a second portion P2. The first portion P1 may have a first height H1 from the seating surface 22 of the substrate stage 20. The second portion may have a second height H2 from the seating surface 22 of the substrate stage 20. The second height H2 may be greater than the first height H1. Since the lower surface 102 of the head portion 100 has the predetermined angle θ, the first portion P1 and the second portion P2 may have the first height H1 and the second height H2 different from each other. For example, each of the first and second portions P1 and P2 may be referred to as a line that is provided on the lower surface 102. The first and second portions P1 and P2 may be parallel to each other. A step difference S1 between the first height H1 and the second height H2 may be within a range of 50 μm to 1100 μm. A height difference between the second semiconductor device 40 and the first semiconductor device 30 may gradually increase from the first portion P1 to the second portion P2. In other words, the step difference S1 may increase as a point moves horizontally from the first portion P1 to the second portion P2.

The head portion 100 may include an elastic material. For example, the head portion 100 may include silicone rubber. The head portion 100 including the elastic material may be elastically deformed in a process of bonding the second semiconductor device 40 onto the first semiconductor device 30. As the head portion 100 contracts elastically, a contact portion where the first and second semiconductor devices 30 and 40 come into contact may shift.

When the contact portion where the first and second semiconductor devices 30 and 40 contact each other shifts, the head portion 100 may transfer a position of pressure that is applied on the second semiconductor device 40 from the first portion P1 toward the second portion P2. As the head portion 100 transfers the pressurized point from the first portion P1 toward the second portion P2, voids V between the first and second semiconductor devices 30 and 40 may be discharged to the outside as illustrated in FIGS. 5 and 6.

The head portion 100 may have a predetermined Young's modulus. ‘The predetermined Young's modulus may enable the head portion 100 to convey pressure when bonding the second semiconductor device 40 onto the first semiconductor device 30 during the bonding process. The head portion 100 may sufficiently transmit the pressure through the predetermined Young's modulus without causing damages to the second semiconductor device 40.

The head portion 100 may deform the second semiconductor device 40 through the predetermined Young's modulus, and the head portion 100 may transfer the pressurized point from the first portion P1 toward the second portion P2. Since the head portion 100 moves the pressurized point from the first portion P1 toward the second portion P2, the voids V between the first and second semiconductor devices 30 and 40 may be discharged to the outside as illustrated in FIGS. 5 and 6. For example, the predetermined Young's modulus may be within a range of 1 MPa to 50 Mpa.

The head portion 100 may include a plurality of vacuum introduction lines 110 that are configured to apply vacuum pressure to temporarily hold the second semiconductor device 40 onto the lower surface 102, and a plurality of vacuum holes 112 connected to the vacuum introduction lines 110 to apply the vacuum pressure. The head portion 100 may include a material that has sufficient strength and rigidity to withstand the vacuum pressure. The vacuum introduction lines 110 may be connected to a vacuum generator that generates the vacuum pressure, to receive the vacuum pressure. The plurality of vacuum holes 112 may extend to the lower surface 102. The vacuum introduction lines 110 extend vertically towards the lower surface 102, and a length of the vacuum introduction lines 110 may be greater near the first portion P1 than near the second portion P2.

In example embodiments, the transfer portion 200 may be provided on the head portion 100 to move the head portion 100. The transfer portion 200 may move in a horizontal direction or a vertical direction on the substrate stage 20.

The transfer portion 200 may press an upper portion of the head portion 100 such that the first and second semiconductor devices 30 and 40 are bonded to each other. The transfer portion 200 may transfer the pressure between the first and second semiconductor devices 30 and 40 through the head portion 100. When the first and second semiconductor devices 30 and 40 are bonded to each other, the transfer portion 200 may detach the head portion 100 from the second semiconductor device 40.

The transfer portion 200 may pressurize the head portion 100 from the first portion P1 toward the second portion P2. When the transfer portion 200 lowers the head portion 100 on which the second semiconductor device 40 is held, the first and second semiconductor devices 30 and 40 may contact each other. The first and second semiconductor devices 30 and 40 may contact each other on the first portion P1 earlier than the second portion P2. Since the lower surface 102 of the head portion 100 has the predetermined angle θ, the transfer portion 200 may move and transfer the pressurized point from the first portion P1 where the first and second semiconductor devices 30 and 40 first contact each other, to the second portion P2. Before the first and second semiconductor devices 30 and 40 contact each other, the second semiconductor device 40 may be positioned at the predetermined angle θ by virtue of its connection to the lower surface 102 of the head portion 100.

The transfer portion 200 may press the head portion 100 with a predetermined pressure. The transfer portion 200 may deform the second semiconductor device 40 through the predetermined pressure in the process of bonding the second semiconductor device 40 onto the first semiconductor device 30.

Since the transfer portion 200 deforms the second semiconductor device 40 through the predetermined pressure, the pressurized point between the first and second semiconductor devices 30 and 40 may gradually move from the first portion P1 to the second portion P2. Since the pressurized point gradually moves from the first portion P1 to the second portion P2, the voids V between the first and second semiconductor devices 30 and 40 may be discharged to the outside without damaging the second semiconductor device 40 as illustrated in FIGS. 5 and 6. For example, the predetermined pressure may be within a range of 10 Pa to 100 Pa.

In example embodiments, the bonding apparatus 10 may further include a heating portion 300. The heating portion 300 may apply heat to the head portion 100 to adhere the first and second semiconductor devices 30 and 40. The heating portion 300 may be provided on a lower surface of a heat blocking member 310. The heating portion 300 may be provided on an upper surface of a heat transfer member 320. The heating portion 300 may be provided between the heat blocking member 310 and the heat transfer member 320 to apply the heat in one direction. The heating portion 300 may be in direct contact with the heat blocking member 310 and the heat transfer member 320.

The second bonding pads 44 of the second semiconductor device 40 may be bonded to the first connecting pads 34 provided on the first upper surface 32a of the first semiconductor device 30 by the heat applied from the heating portion 300. The heating portion 300 may include a rectangular plate. Additionally, the heating portion 300 may include a ceramic heater that includes an electrically resistive heating wire. The heating portion 300 may include a thermally conductive material.

Hereinafter, a method of bonding semiconductor devices using the bonding apparatus in FIG. 1 will be described in detail.

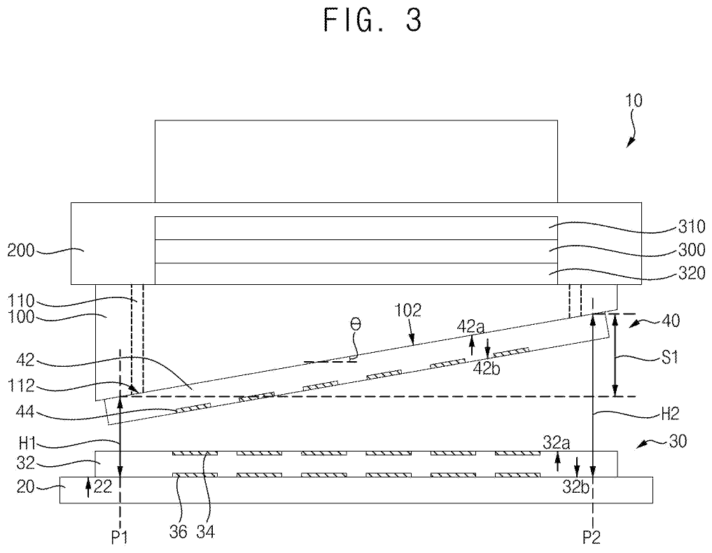

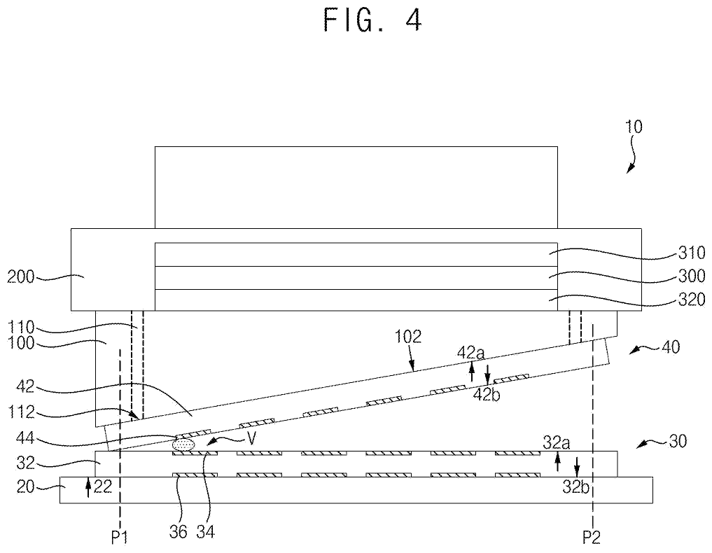

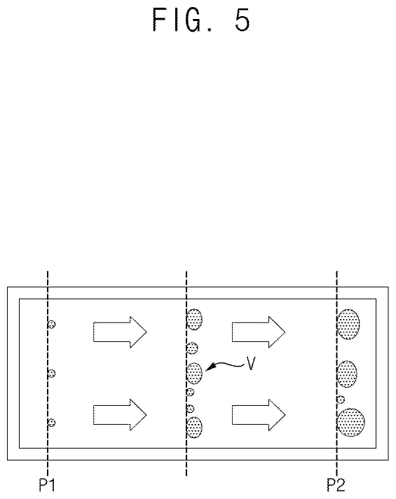

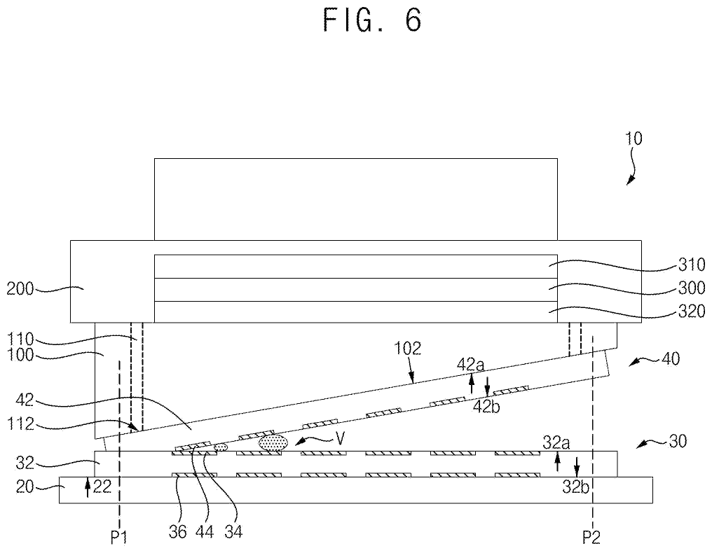

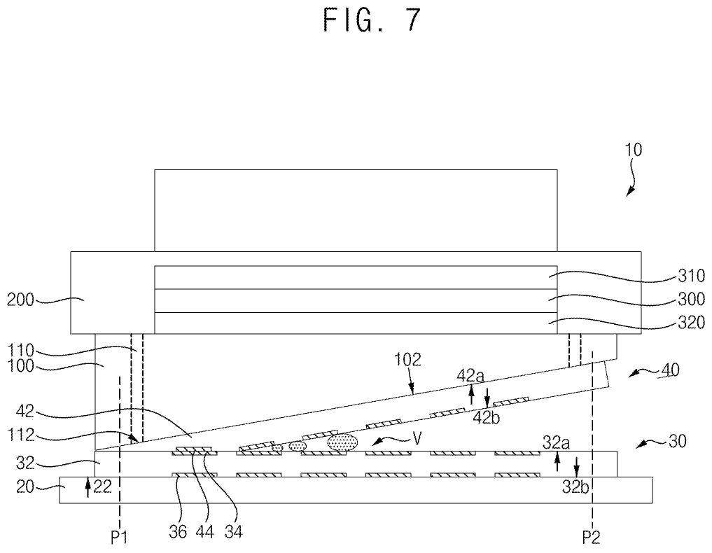

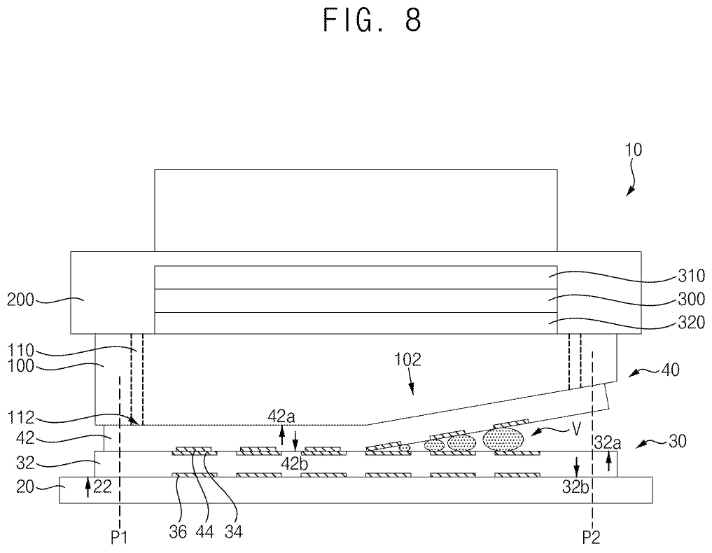

FIGS. 3 to 9 are views illustrating processes of bonding a plurality of semiconductor devices using the bonding apparatus in FIG. 1.

Referring to FIGS. 3 and 4, first, a second semiconductor device 40 may be temporarily held on a head portion 100. The second semiconductor device 40 may be temporarily held on a lower surface 102 of a head portion 100 by vacuum pressure.

In example embodiments, the second semiconductor device 40 may be secured on the head portion 100 such that a second lower surface 42b faces a first upper surface 32a of a first semiconductor device 30. Second bonding pads 44 that are exposed from the second lower surface 42b of the second semiconductor device 40 may be arranged to face first connecting pads 34 that are exposed from the first upper surface 32a of the first semiconductor device 30.

As illustrated in FIG. 3, the head portion 100 may have the lower surface 102 that has a predetermined angle θ with respect to a seating surface 22 of a substrate stage 20. The lower surface 102 of the head portion 100 may have a first portion P1 having a first height H1 from the seating surface 22 of the substrate stage 20, and a second portion P2 having a second height H2 greater than the first height H1. A step difference S1 between the first height H1 and the second height H2 of the head portion 100 may be formed by the predetermined angle θ. A height difference between the second semiconductor device 40 and the first semiconductor device 30 may gradually increase from the first portion P1 to the second portion P2. In other words, the step difference S1 may increase as a point moves horizontally from the first portion P1 to the second portion P2.

As illustrated in FIG. 4, the second semiconductor device 40 may be arranged to be inclined at the predetermined angle θ with respect to the seating surface 22 of the substrate stage 20 since the second semiconductor device 40 is held on the lower surface 102 of the head portion 100. The second semiconductor device 40 secured on the lower surface 102 of the head portion 100 may be lowered in a vertical direction by a transfer portion 200.

As the transfer portion 200 guides the second semiconductor device 40 downward, the second semiconductor device 40 may contact a section of the first semiconductor device 30 located at the first portion P1. Here, the second semiconductor device 40 may be spaced apart from the first semiconductor device 30 at the second portion P2. When the first and second semiconductor devices 30 and 40 make contact with each other, voids V may be formed between the first and second semiconductor devices 30 and 40. The voids V may be formed adjacent to the first portion P1 where the first and second semiconductor devices 30 and 40 make contact with each other.

FIGS. 5 to 8 are views illustrating processes of discharging the voids between the semiconductor devices to be stacked.

Referring to FIGS. 5 to 8, the voids V may be discharged to the outside during a bonding process of the first and second semiconductor devices 30 and 40. Since the second semiconductor device 40 is in contact with the first semiconductor device 30 while tilted at the predetermined angle θ, the voids V may gradually move between the first and second semiconductor devices 30 and 40.

In example embodiments, as illustrated in FIGS. 5 and 6, when the transfer portion 200 descends, the first and second semiconductor devices 30 and 40 may first make contact with each other on the first portion P1 with the predetermined angle θ. The voids V may be generated in the first portion P1 where the first and second semiconductor devices 30 and 40 contact each other.

As illustrated in FIGS. 5, 7 and 8, the voids V may move from the first portion P1 toward the second portion P2. For example, the voids V may move horizontally as the second semiconductor device 40 bonds with the first semiconductor device 30, from the first portion P1 to the second portion P2 along the first upper surface 32a. During the movement of the voids V, an amount and a size of the voids V may be increased.

As the first and second semiconductor devices 30 and 40 contact each other on the first portion P1, the transfer portion 200 may continuously apply the pressure to the second upper surface 42a of the second semiconductor device 40. The voids V may be moved between the first and second semiconductor devices 30 and 40 by the pressure.

The head portion 100 may include an elastic material, which may be elastically deformed (contracted) in the process of bonding the first and second semiconductor devices 30 and 40 each other. As the elastic material gradually contracts, the bonding between the first and second semiconductor devices 30 and 40 may progress gradually from the first portion P1 to the second portion P2. Since the elastic material is elastically contracted, damage may not be caused to the first and second semiconductor devices 30 and 40.

The head portion 100 may have a predetermined Young's modulus, and the head portion 100 may deform the second semiconductor device 40 through the predetermined Young's modulus. Since the head portion 100 has a sufficient Young's modulus, the pressure may be sufficiently transferred to the second semiconductor device 40. Since the deformation is generated within the second semiconductor device 40, the bonding of the first and second semiconductor devices 30 and 40 may proceed gradually from the first portion P1 to the second portion P2.

Since the first and second semiconductor devices 30 and 40 are gradually bonded to each other from the first portion P1 to the second portion P2, the voids V between the first and second semiconductor devices 30 and 40 may gradually move from the first portion P1 to the second portion P2.

For example, the first and second portions P1 and P2 may extend parallel to each other. Since the first and second portions P1 and P2 extend parallel to each other, the voids V between the first and second portions P1 and P2 may be moved from the first portion P1 toward the second portion P2 along a tangential line. The tangential line may be referred to as a portion where the first and second semiconductor devices 30 and 40 make contact with each other.

As illustrated in FIG. 9, the first and second semiconductor devices 30 and 40 may be bonded to each other. In the process of bonding the first and second semiconductor devices 30 and 40 each other, the voids V may be discharged from the first and second semiconductor devices 30 and 40 to the outside.

The second semiconductor device 40 may be mounted on the first semiconductor device 30 by a hybrid copper bonding method. Thus, the first connecting pad 34 and the second bonding pad 44 between the first semiconductor device 30 and the second semiconductor device 40 may be bonded to each other by Cu—Cu Hybrid Bonding. For example, pad to pad direct bonding may be formed.

As described above, a bonding apparatus 10 may bond the second semiconductor device 40 to the first semiconductor device 30 provided on a substrate stage 20 by the head portion 100. The head portion 100 on which the second semiconductor device 40 is secured may have the first and second portions P1 and P2 having the different first and second heights H1 and H2 from the seating surface 22. Since the second height H2 of the second portion P2 is greater than the first height H1 of the first portion P1, the second semiconductor device 40 secured on the lower surface 102 of the head portion 100 may be arranged to be inclined at the predetermined angle θ.

As the transfer portion 200 guides the second semiconductor device 40 downward, the second semiconductor device 40 may contact a section of the first semiconductor device 30 located at the first portion P1. When the transfer portion 200 presses the head portion 100 in the vertical direction, the second semiconductor device 40 may be bonded to the first semiconductor device 30 from the first portion P1 toward the second portion P2. For example, as the transfer portion 200 is pushing down the second semiconductor device 40, the first portion P1 may directly touch the first semiconductor device 30 while the second portion P2 still maintains a distance from the first semiconductor device 30. Since the first and second semiconductor devices 30 and 40 are bonded to each other from the first portion P1 toward the second portion P2, the voids V between the first and second semiconductor devices 30 and 40 may be moved from the first portion P1 toward the second portion P2 to be discharged to the outside.

Further, since the transfer portion 200 continuously presses the head portion 100 from the first portion P1 toward the second portion P2, the bonding apparatus 10 may prevent excessive deformation and internal peeling of the second semiconductor device 40.

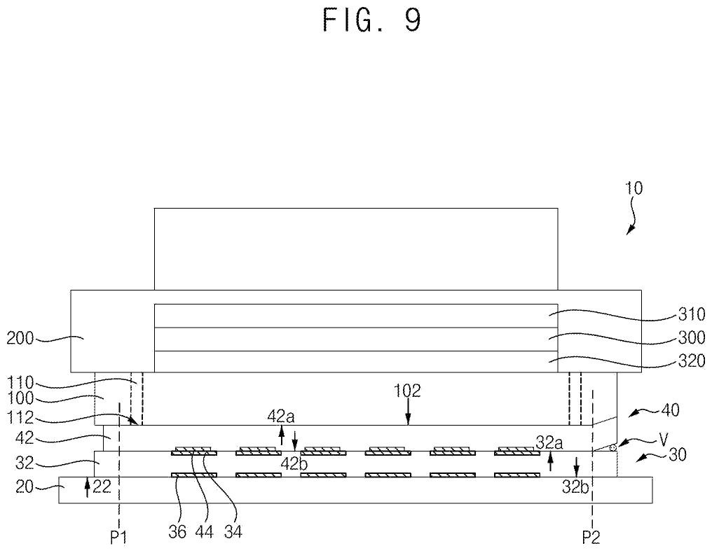

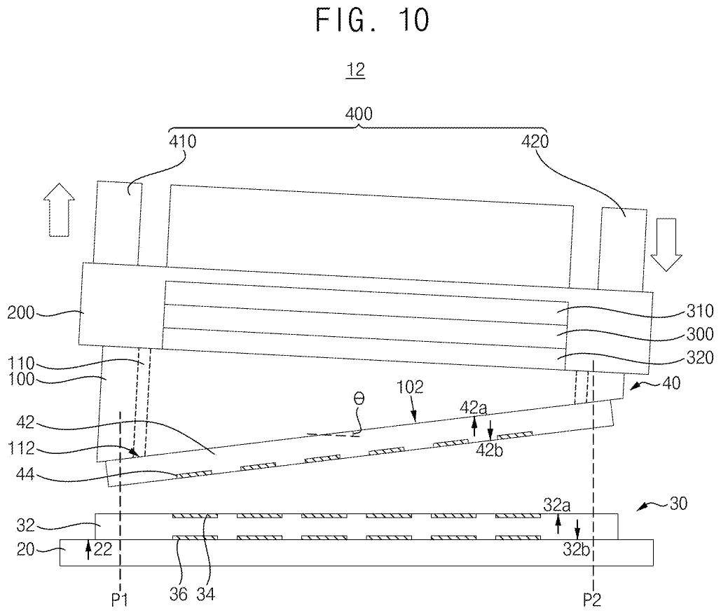

FIG. 10 is a view illustrating a bonding apparatus having a rotating portion in accordance with example embodiments. The bonding apparatus may be substantially the same as or similar to the bonding apparatus described with reference to FIGS. 1 and 2 except for an additional rotating portion. Thus, same reference numerals will be used to refer to the same or like elements and any further repetitive explanation concerning the above elements will be omitted.

Referring to FIG. 10, a bonding apparatus 12 for a semiconductor device may include a substrate stage 20 on which a first semiconductor device 30 is placed, a head portion 100 configured to temporarily hold a second semiconductor device 40 on the substrate stage 20, a transfer portion 200 configured to move the head portion 100, and a rotating portion 400 configured to rotate the transfer portion 200.

In example embodiments, the rotating portion 400 may be provided on the transfer portion 200. The rotating portion 400 may include first and second actuators 410 and 420 provided on the transfer portion 200. The first and second actuators 410 and 420 may be provided on the transfer portion 200 to be spaced apart from each other. The first and second actuators 410 and 420 may apply external forces to the transfer portion 200 in opposite directions to rotate the transfer portion 200. The first and second actuators 410 and 420 may apply the external forces in the vertical direction to rotate the transfer portion 200.

In particular, when the first actuator 410 applies a pulling force on the transfer portion 200, the second actuator 420 may apply a pushing force on the transfer portion 200. Alternatively, when the first actuator 410 applies the pushing force on the transfer portion 200, the second actuator 420 may apply the pulling force on the transfer portion 200. For example, the first actuator 410 may exert a force that pulls the transfer portion 200 towards the rotating portion 400 while the second actuator 420 exerts a force that pushes the transfer portion 200 towards the transfer portion 200.

As illustrated in FIG. 10, while the transfer portion 200 presses the head portion 100, the rotating portion 400 may rotate the transfer portion 200 such that a predetermined angle θ with respect to the seating surface 22 of the substrate stage 20 of the second semiconductor device 40 gradually decreases. The rotation portion 400 may rotate the transfer portion 200 such that the second semiconductor device 40 provided on the head portion 100 may gradually come into contact with the first semiconductor device 30. As the transfer portion 200 rotates, the head portion 100 may rotate, and accordingly the second semiconductor device 40 secured on the head portion 100 may rotate.

For example, in the process of bonding the first and second semiconductor devices 30 and 40, the first actuator 410 provided adjacent to the first portion P1 may apply the pushing force onto the transfer portion 200, and the second actuator 420 provided adjacent to the second portion P2 may apply the pulling force onto the transfer portion 200.

Accordingly, the first and second actuators 410 and 420 may raise the first portion P1 from the substrate stage 20 and may lower the second portion P2 to the substrate stage 20. Since the first portion P1 is raised and the second portion is lowered, the second semiconductor device 40 may be stably bonded to the first semiconductor device 30.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as set forth in the claims.

What is claimed is:

1. A bonding apparatus for a semiconductor device, comprising:
a substrate stage having a seating surface on which a first semiconductor device is placed;
a head portion having a lower surface, the head portion configured to hold a second semiconductor device on the lower surface to face the first semiconductor device, the lower surface including a first portion having a first height from the seating surface and a second portion having a second height from the seating surface, the second height being greater than the first height, the lower surface being inclined at an angle with respect to the seating surface; and
a transfer portion provided on the head portion to move the head portion, the transfer portion configured to press the head portion from the first portion to the second portion such that the first and second semiconductor devices are bonded to each other.

2. The bonding apparatus of claim 1, wherein the head portion further includes a vacuum introduction line that is configured to apply vacuum pressure on the lower surface of the head portion.

3. The bonding apparatus of claim 1, wherein the angle is within a range of 1 degree to 45 degrees.

4. The bonding apparatus of claim 1, wherein a difference between the first height and the second height is within a range of 50 μm to 1100 μm.

5. The bonding apparatus of claim 1, wherein the transfer portion is configured to press the head portion at a pressure, and
the pressure is within a range of 10 Pa to 100 Pa.

6. The bonding apparatus of claim 1, wherein the head portion includes silicone rubber.

7. The bonding apparatus of claim 1, wherein the head portion has a predetermined Young's modulus, and
the predetermined Young's modulus is within a range of 1 MPa to 50 MPa.

8. The bonding apparatus of claim 1, wherein the first and second portions are parallel to each other.

9. The bonding apparatus of claim 1, further comprising:
a rotating portion configured to rotate the transfer portion such that the angle of the lower surface decreases while the transfer portion presses the head portion.

10. The bonding apparatus of claim 1, wherein the first and second semiconductor devices are bonded to each other by a hybrid copper bonding process.

11. A bonding apparatus for a semiconductor device, comprising:
a substrate stage having a seating surface on which a first semiconductor device is supported;
a head portion having a lower surface inclined at a predetermined angle with respect to the seating surface of the substrate stage, the head portion configured to hold a second semiconductor device on the lower surface of the head portion to face the first semiconductor device; and
a transfer portion provided on the head portion to move the head portion, the transfer portion configured to press the second semiconductor device onto the first semiconductor device from a first portion of the lower surface to a second portion of the lower surface, the first portion of the lower surface having a first height from the seating surface, the second portion of the lower surface having a second height from the seating surface, the second height being greater than the first height.

12. The bonding apparatus of claim 11, wherein the head portion further includes a vacuum introduction line that is configured to apply vacuum pressure on the lower surface of the head portion to hold the second semiconductor device.

13. The bonding apparatus of claim 11, wherein the predetermined angle is within a range of 1 degree to 45 degrees.

14. The bonding apparatus of claim 11, wherein a step difference between the first height and the second height is within a range of 50 μm to 1100 μm.

15. The bonding apparatus of claim 11, wherein the transfer portion is configured to press the head portion at a predetermined pressure, and
the predetermined pressure is within a range of 10 Pa to 100 Pa.

16. The bonding apparatus of claim 11, wherein the head portion includes silicone rubber.

17. The bonding apparatus of claim 11, wherein the head portion has a predetermined Young's modulus, and
the predetermined Young's modulus is within a range of 1 MPa to 50 MPa.

18. The bonding apparatus of claim 11, further comprising:
a rotating portion configured to rotate the transfer portion such that the predetermined angle of the lower surface decreases while the transfer portion presses the head portion.

19. The bonding apparatus of claim 11, wherein the first and second semiconductor devices are bonded to each other by a hybrid copper bonding process.

20. A bonding apparatus for a semiconductor device, comprising:
a substrate stage having a seating surface that is configured to support a first semiconductor device during a process of bonding a second semiconductor device on the first semiconductor device;
a head portion having a lower surface that is inclined at a predetermined angle with respect to the seating surface of the substrate stage, the head portion configured to temporarily hold the second semiconductor device on the lower surface using vacuum pressure such that the second semiconductor device faces the first semiconductor device; and
a transfer portion provided on the head portion, the transfer portion configured to press the second semiconductor device onto the first semiconductor device from a first portion of the lower surface toward a second portion of the lower surface, the first portion of the lower surface having a first height from the seating surface, the second portion of the lower surface having a second height from the seating surface, the second height being greater than the first height.
